(19) United States
(12) Patent Application Publication
(10) Pub. No.: US 2008/0088035 A1
(43) Pub. Date: Apr. 17, 2008

(54) Circuit board assembly

(75) Inventors: Chih-Hang Chao, Tu-Cheng (TW); Yu-Hsu Lin, San Jose, CA (US); Jeng-Da Wu, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,881

(22) Filed: Oct. 17, 2006

(51) Int. Cl. H01L 23/48

(52) U.S. Cl. 257/781; 257/E23.01

(57) ABSTRACT

A circuit board assembly includes a circuit board and a semiconductor chip mounted on the board. The semiconductor chip includes a plurality of solder spots arrayed thereon in a matrix pattern. The solder spots except those located at corners of the pattern are jointed to the board via tin balls to form signal transmitting channels for transmitting signals between the board and the chip. Should the circuit board suffer impact, damage to the signal transmitting channels may be effectively minimized or prevented.

### FIELD OF THE INVENTION

The present invention relates to circuit board assemblies, more particularly to a circuit board assembly configured to minimize or prevent damage to a semiconductor chip on a circuit board when the circuit board suffers impact.

### DESCRIPTION OF RELATED ART

A semiconductor chip is usually mounted on a printed circuit board by jointing solder spots of the semiconductor chip to the printed circuit board via tin balls. A conventional tin ball is made with lead. Because of good capability of lead for resisting shock, the tin ball is not easily damaged. However, due to the dangers of leaded tin balls polluting environment and damaging health of people, nonleaded tin balls are now commonly used in the process of mounting a semiconductor chip to a printed circuit board. However, because of poor capability of non-leaded tin balls to resist shock, they are easily damaged when the printed circuit board suffers an impact, thereby affecting signal transmission between the semiconductor chip and the board.

What is needed, therefore, is a circuit board assembly which provides good signal transmission between a semiconductor chip and a circuit board even after the circuit board suffers an impact.

### SUMMARY OF THE INVENTION

A circuit board assembly includes a circuit board and a semiconductor chip mounted on the board. The semiconductor chip includes a plurality of solder spots arrayed thereon in a matrix pattern. The solder spots except those located at corners of the pattern are jointed to the board via tin balls to form signal transmission channels for transmitting signals between the board and the chip. Should the circuit board suffer impact, quality of signal transmission capabilities are maintained between the semiconductor chip and the board since no signal transmission channels exist at the corners where damage is most likely to occur.

Other advantages and novel features will be drawn from the following detailed description of preferred embodiments with attached drawings, in which:

### BRIEF DESCRIPTION OF THE DRAWINGS

FIG. 1 is an isometric view of a circuit board assembly in accordance with a preferred embodiment of the present invention;

FIG. 2 is a cross-sectional view of the circuit board assembly in accordance with the preferred embodiment of the present invention;

FIG. 3 is a graph of acceleration when the circuit board assembly suffers impact;

FIG. 4 is a diagram showing distribution of solder spots of a semiconductor and tin balls of the circuit board assembly in accordance with a first embodiment of the present invention;

FIG. 5 is a diagram showing distribution of solder spots of a semiconductor and tin balls of the circuit board assembly in accordance with a second embodiment of the present invention; and

FIG. 6 is a diagram showing distribution of solder spots of a semiconductor and tin balls of the circuit board assembly in accordance with a third embodiment of the present invention.

### DETAILED DESCRIPTION OF THE INVENTION

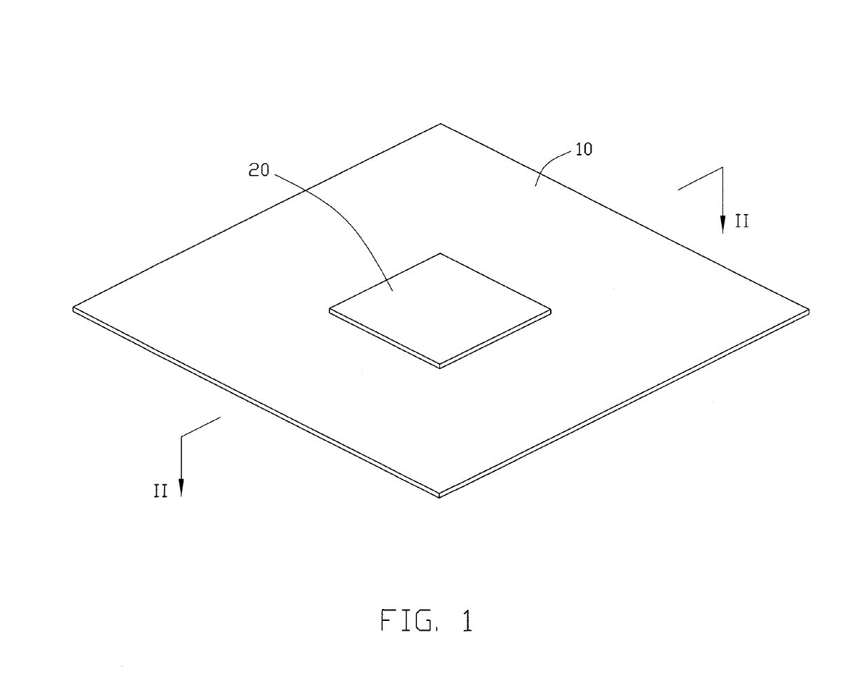

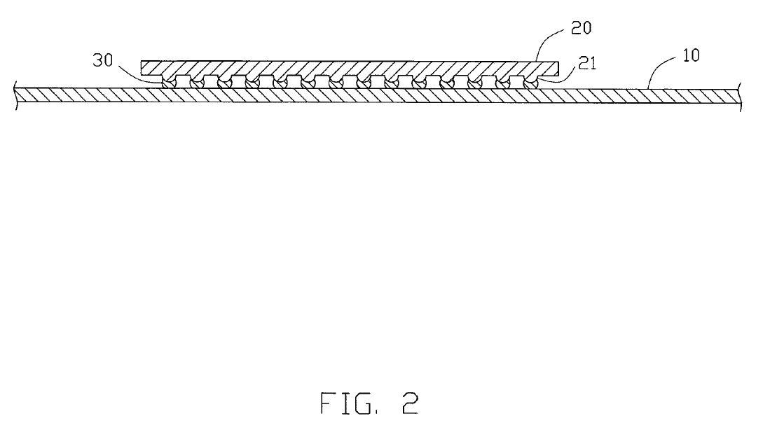

Referring to FIG. 1 and FIG. 2, the circuit board assembly in accordance with the present invention includes a printed circuit board (PCB) 10 and a semiconductor chip 20 jointed on the PCB 10. A plurality of solder spots 21 is arrayed in a rectangular area of the semiconductor chip 20 in a matrix pattern. Each solder spot can act as a conduit for transmission of signals. Each solder spot 21 is jointed on the PCB 10 by a tin ball 30. Each solder spot 21 cooperates with the corresponding tin ball 30 to form a signal transmission channel.

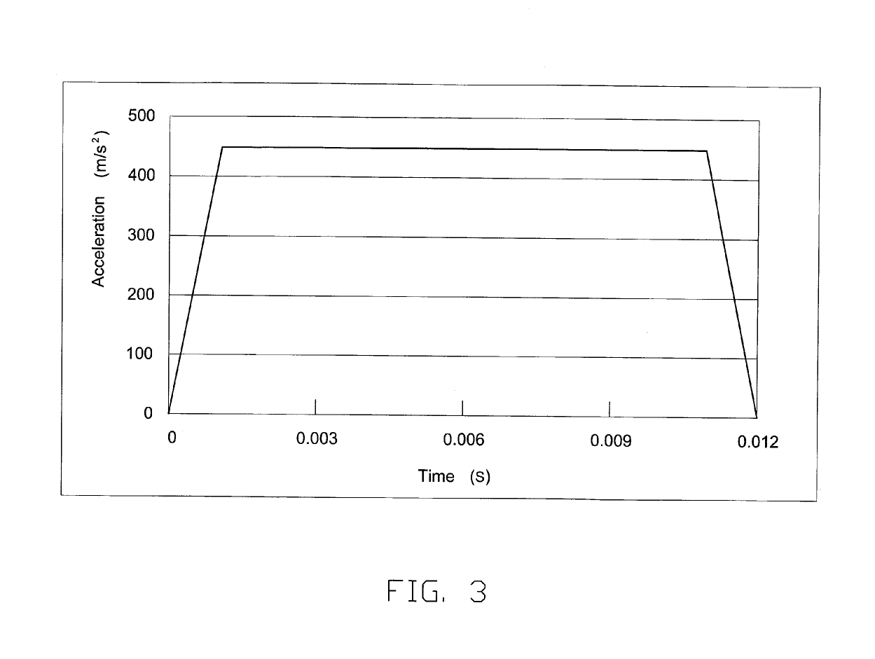

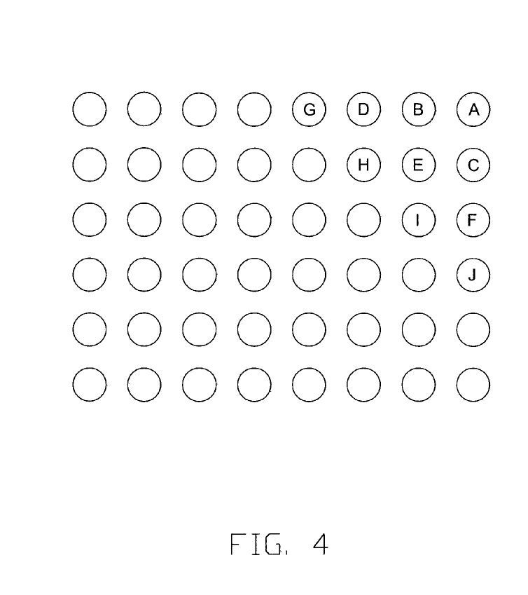

A software LS-DYNA is used for simulating stress distribution on the tin balls 30 when the PCB 10 suffers an impact. The simulating condition is set as follows: the semiconductor chip 20 is jointed on the center of the PCB 10; the initial velocity of the PCB 10 is 4.86 meters/second when the PCB 10 suffers an impact. An acceleration curve (shown in FIG. 3) is used for simulating the stress on four corners of the PCB 10. The maximal acceleration of the four corners is determined to be 45 gravities when the PCB 10 is struck. The simulation according to above conditions shows that the stress on the tin balls 30 is greatest at corners of the semiconductor chips 20. Referring also to FIG. 4, the stress on one of the corners of the solder spot/tin ball array during an impact is detailed in a table below:

| Tin ball | Stress in megapascals (Mpa) |
|---|---|
| A | 84.30 |
| B | 51.54 |
| C | 49.05 |
| D | 37.39 |
| E | 35.04 |
| F | 33.66 |
| G | 30.75 |
| H | 30.50 |
| I | 30.35 |
| J | 26.66 |

According to the above table, the tin ball A at the corner of the array suffers maximal stress. The stress on the tin balls 30 significantly decreases through a second diagonal row of tin balls 30 away from the corner, and even more in third and fourth diagonal rows. When the semiconductor chip 20 is disposed on other places of the PCB 10, results of simulated impacts are generally same as aforesaid. That is, tin balls 30 located in corners of rectangular areas are easiest to be damaged when the PCB 10 suffers an impact. Therefore, in the design process of the semiconductor chip 20 in accordance with the embodiment of the present invention, solder spots 21 of the corners of the array are configured not to act as transmission conduits. Solder spots 21 of the second and/or third diagonal rows may be so configured as well. Thus, should the PCB 10 suffer an impact, chances that transmitting channels between the semiconductor chip 20 and the PCB 10 suffer damage are minimized or possibly eliminated.

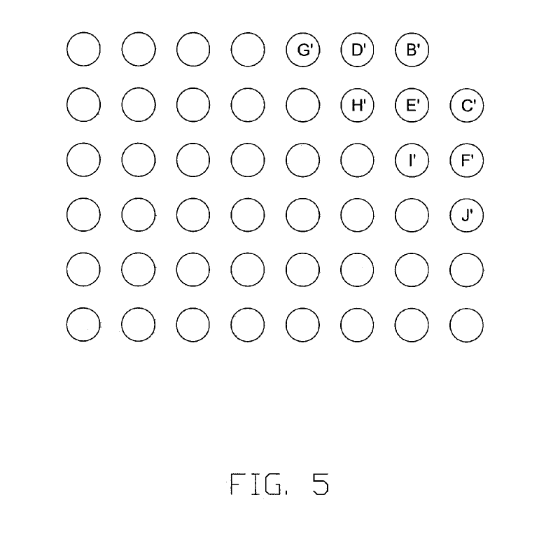

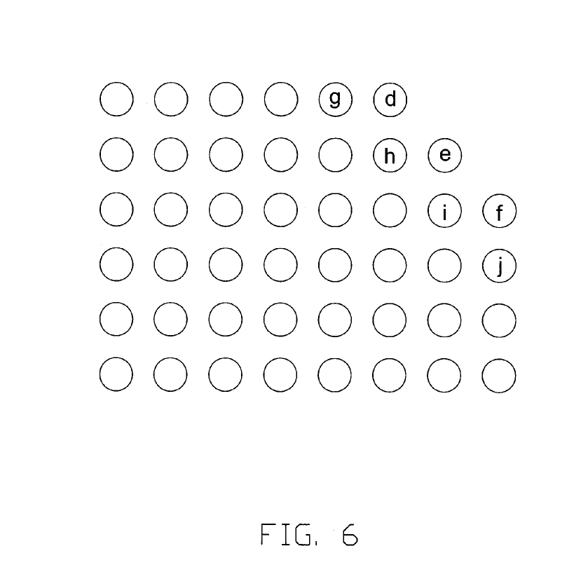

Referring also to FIGS. 5 and 6, according to the principle described above, second and third embodiments are presented. In the second embodiment, corner solder spot 21 and corresponding tin ball 30 at each corner (only one corner shown in FIG. 5) are omitted and solder spots B′-J′ are configured not to act as transmission conduits. With omission of the corner solder spot 21 and tin ball 30, stress from a simulated impact on the adjacent tin balls B′ and C′ was found to be 66.60 MPa, 20 percent less than on the tin ball A of the first embodiment. Referring to the third embodiment, three solder spots 21 and tin balls 30 (corner and adjacent diagonal row) at each corner (only one corner shown in FIG. 6) are omitted, stress on the tin balls 30 in next adjacent diagonal row containing tin balls d-f is found to be only 53.69 MPa in a simulated impact, 36 percent less than on the tin ball A. Therefore, should the PCB 10 suffer an impact, chances that transmitting channels between the semiconductor chip 20 and the PCB 10 will suffer damage are minimized or possibly eliminated with the second and third embodiments.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A circuit board assembly, comprising:
a circuit board; and
a semiconductor chip mounted on the board, the semiconductor chip comprising a plurality of solder spots arrayed thereon in a matrix pattern, each solder spot jointed to the board via a tin ball; wherein the solder spots except those located at corner portions of the pattern, act as conduits for transmission of signals and cooperate with the corresponding tin balls to form signal transmitting channels for transmitting signal between the chip and the board.

2. The circuit board assembly as described in claim 1, wherein the matrix pattern is a square or rectangular pattern.

3. The circuit board assembly as described in claim 1, wherein the excepted solder spots not act as conduits are respectively distributed in an area enclosed by the corner of the pattern and a diagonal row of the pattern away from the corner.

4. A circuit board assembly, comprising:
a circuit board; and
a semiconductor chip mounted on the board, the semiconductor chip comprising a plurality of solder spots provided in an array of areas thereof, the array of areas having a plurality of corners, each solder spot jointed to the board via a tin ball; wherein each solder spot together with the corresponding tin ball forms a signal transmitting channel, and at least one of the areas at each corner is not occupied by a solder spot.

5. The circuit board assembly as described in claim 4, wherein the array of areas is a square or a rectangular.

6. The circuit board assembly as described in claim 4, wherein the at least one of the areas is enclosed by the corner and a diagonal row of the array of areas away from the corner.

7. A circuit board assembly, comprising:
a circuit board; and
a semiconductor chip mounted on the board, the semiconductor chip comprising a plurality of solder spots arranged in a matrix pattern with corners, wherein
the solder spots except at least one located at vicinity of the corners are jointed to the board via tin balls to form signal transmitting channels for transmitting signals between the board and the chip.

8. The circuit board assembly as claimed in claim 7, wherein the excepted at least one solder spot comprises a plurality of solder spots arranged in an area defined by one of the corners and a diagonal row of the matrix pattern away from the one of the corners.

9. The circuit board assembly as claimed in claim 7, wherein the excepted at least one solder spot comprises a plurality of solder spots arranged in an area defined by diagonal rows of the matrix pattern away from one of the corners.
